(19) United States
(12) Patent Application Publication
(10) Pub. No.: US 2007/0126113 A1
(43) Pub. Date: Jun. 7, 2007

(54) Semiconductor device

(75) Inventors: Hiroaki Ohkubo, Kanagawa (JP); Yasutaka Nakashiba, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 11/607,009

(22) Filed: Dec. 1, 2006

(30) Foreign Application Priority Data
Dec. 6, 2005 (JP) 2005-351976

(51) Int. Cl. H01L 23/12

(52) U.S. Cl. 257/700

(57) ABSTRACT

It is concerned in conventional semiconductor devices that a presence of a heat sink promotes propagating noise through the semiconductor chip. A semiconductor device includes a substrate, interconnects (first interconnects), interconnects (second interconnect), a semiconductor chip and a heat sink (electroconductive member). The interconnect is the interconnect that is electrically coupled to an internal interconnect of the semiconductor chip. On the contrary, the interconnect is the interconnect that is electrically coupled to a back surface (first surface) of the semiconductor chip. The interconnects are electrically insulated from the interconnects in the substrate. The semiconductor chip is provided on the substrate. A predetermined fixed potential is presented at the back surface of such semiconductor chip through the interconnect.

This application is based on Japanese patent application No. 2005-351,976, the content of which is incorporated hereinto by reference.

### BACKGROUND

1. Technical Field

The present invention relates to a semiconductor device.

2. Related Art

Typical conventional semiconductor devices include, for example, a semiconductor device described in Japanese Patent Laid-Open No. 2005-223,008 and a semiconductor device described in an article written by KAJIWARA, Mamoru, et al., entitled “Taking an opportunity afforded by a high end BGA product to reconsider whether an instruction for providing Pb-free ROHS is appropriate or not” or “Hai end muke BGA hin wo Pb-free RoHS shirei no minaoshino kikkakeni”, Nikkei Electronics, Jan. 3, 2005, pp. 113 to 120. In semiconductor devices described in these literatures, a semiconductor chip is flip-chip mounted on a substrate. Further, a back surface of the semiconductor chip is provided with a heat sink via an adhesive agent.

Nevertheless, it is concerned in such type of semiconductor device that a presence of a heat sink promotes noise propagation through the semiconductor chip. It is considered for example that, as shown in FIG. 4, noise generated in an impurity diffusion layer 106 in a semiconductor substrate 102 reflects by a heat sink 104, and the reflected noise propagates to an impurity diffusion layer 108. Alternatively, it is also considered that, as shown in FIG. 5, noise generated in the impurity diffusion layer 106 propagates to the impurity diffusion layer 108 through an internal of heat sink 104. Here, a typical impurity diffusion layer 106 is, for example, a P⁺ diffusion layer provided in a digital circuit region, and a typical impurity diffusion layer 108 is, for example, a P⁺ diffusion layer provided in an analog circuit region.

### SUMMARY OF THE INVENTION

According to one aspect of the present invention, there is provided a semiconductor device, comprising: a substrate; a semiconductor chip provided on the substrate; an electroconductive member provided on a first surface of the semiconductor chip, the first surface being a surface that is an opposite side of a surface thereof facing the substrate; a first interconnect, provided in the substrate and electrically coupled to an internal interconnect of the semiconductor chip; and a second interconnect, provided in the substrate and electrically coupled to the first surface of the semiconductor chip, wherein a predetermined fixed potential is applied to the first surface of the semiconductor chip through the second interconnect, and the first interconnect is electrically insulated from the second interconnect in the substrate.

In the semiconductor device according to the above-described aspect of the present invention, a fixed potential is applied to the first surface of semiconductor chip through the second interconnect. Here, the second interconnect is electrically insulated from the first interconnect, which is an interconnect that is electrically coupled to an internal interconnect of semiconductor chip. In other words, the fixed potential is applied to the first surface of the semiconductor chip through an exclusive interconnect in the substrate. In this configuration, noise generated in a certain region in the semiconductor chip is absorbed by the first surface, so that a promotion of increasing a propagation of noise by the electroconductive member provided on the first surface can be prevented.

According to the present invention, the semiconductor device providing an improved noise resistance can be presented.

### BRIEF DESCRIPTION OF THE DRAWINGS

The above and other objects, advantages and features of the present invention will be more apparent from the following description taken in conjunction with the accompanying drawings, in which:

FIG. 1 is a cross-sectional view, illustrating a semiconductor device according to an embodiment of the present invention;

FIG. 2 is a cross-sectional view, illustrating a semiconductor device according to a modified embodiment of the present invention;

FIG. 3 is a cross-sectional view, illustrating a semiconductor device according to a modified embodiment of the present invention;

FIG. 4 is a cross-sectional view for describing a problem occurred in a conventional semiconductor device; and

FIG. 5 is a cross-sectional view for describing a problem occurred in a conventional semiconductor device.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposed.

Preferable embodiments of semiconductor devices according to the present invention will be described as follows in further detail, in reference to the annexed figures. In all figures, an identical numeral is assigned to an element commonly appeared in the figures, and redundant descriptions thereof will not be repeated.

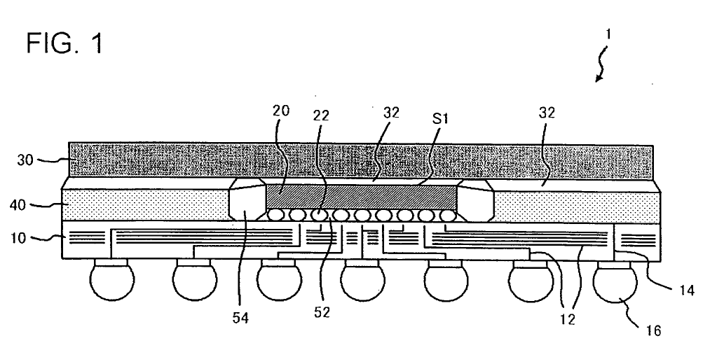

FIG. 1 is a cross-sectional view, illustrating a semiconductor device according to an embodiment of the present invention. A semiconductor device 1 includes a substrate 10, interconnects 12 (first interconnects), interconnects 14 (second interconnect), a semiconductor chip 20 and a heat sink 30 (electroconductive member).

The substrate 10 is, for example, a printed circuit board. The interconnects 12 and the interconnects 14 are provided in the substrate 10. The interconnect 12 is the interconnect that is electrically coupled to an internal interconnect of the semiconductor chip 20. On the other hand, the interconnect 14 is the interconnect that is electrically coupled to a back surface S1 (first surface) of the semiconductor chip 20. The interconnects 12 are electrically insulated from the interconnects 14 in the substrate 10. Therefore, the interconnect 14 is also electrically insulated from an internal interconnect of the semiconductor chip 20.

Solder bumps 16 functioning as external electrode terminals of the semiconductor device 1 are coupled to a back surface of the substrate 10 (a side opposite to the surface facing the semiconductor chip 20). A plurality of solder bumps 16 are provided, and each of the solder bumps 16 is coupled to one of the interconnects 12 and the interconnects 14. In FIG. 1, the rightmost solder bump 16 is coupled to the interconnect 14, and other solder bumps 16 are coupled to the interconnects 12, respectively.

The semiconductor chip 20 is provided on the substrate 10. Specifically, the semiconductor chip 20 is flip-chip mounted onto the substrate 10. More specifically, the semiconductor chip 20 is fixed to the substrate 10 via the solder bumps 22, with the top surface of the semiconductor chip 20 (side facing the interconnect layer) facing toward the substrate 10. Thickness of the semiconductor chip 20 is, for example, equal to or shorter than 300 μm.

A predetermined fixed potential is applied to the back surface S1 of the semiconductor chip 20 through the interconnect 14. Here, the back surface S1 of the semiconductor chip 20 is the surface of the side facing the semiconductor substrate of the semiconductor chip 20. The above-described fixed potential is, for example, ground (GND) potential. In such case, the solder bump 16, which is coupled to the interconnect 14, is coupled to by GND terminal of the substrate which the semiconductor device 1 is mounted (printed circuit board, for example). As described above, when GND potential is applied to the back surface S1 of the semiconductor chip 20 through the dedicated interconnect 14 in the substrate 10, such GND may be particularly called “ideal GND”.

A heat sink 30 is provided on the back surface S1 of the semiconductor chip 20. More specifically, the heat sink 30 is fixed to the back surface S1 of the semiconductor chip 20 via an electroconductive adhesive agent 32. Such heat sink 30 is composed of an electroconductive material. The heat sink 30 has a plan view, which has a larger area than the semiconductor chip 20, and thus covers the entire back surface S1 of the semiconductor chip 20.

A support frame 40 is also provided on the substrate 10. Such support frame 40 is a support member, which is capable of supporting the heat sink 30, and composed of an electroconductive material. In the present embodiment, the support frame 40 is provided so as to surround the semiconductor chip 20. The above-described heat sink 30 is also fixed to such support frame 40 via the electroconductive adhesive agent 32.

The interconnect 14 is coupled to the support frame 40, and a fixed potential is applied to the back surface S1 of the semiconductor chip 20 via these interconnects 14 and the support frame 40. Particularly in the present embodiment, the back surface S1 of the semiconductor chip 20 is electrically coupled to the support frame 40 via the heat sink 30. Therefore, a fixed potential is to be applied to the back surface S1 via the heat sink 30 in addition to the interconnect 14 and the support frame 40.

A spacing between the above-described substrate 10 and the semiconductor chip 20 is filled with an underfill resin 52. Further, in the present embodiment, a spacing between the semiconductor chip 20 and the support frame 40 is filled with a side fill resin 54.

Subsequently, advantageous effects obtainable by employing the semiconductor device 1 will be described. In the semiconductor device 1, a fixed potential is applied to the back surface S1 of the semiconductor chip 20 via the interconnect 14. Here, the interconnect 14 is electrically insulated from any of the interconnects 12, which are the interconnects that are electrically coupled to the internal interconnect of the semiconductor chip 20. In other words, the above-described fixed potential is to be applied to the back surface S1 of the semiconductor chip 20 via the dedicated interconnect in the substrate 10. Having such configuration, a noise generated in a certain region in the semiconductor chip 20 is absorbed by the back surface S1, such that a promotion of increasing a propagation of noise by the heat sink 30 provided on the back surface S1 can be prevented. Thus, the semiconductor device 1 providing an improved noise resistance can be provided. Here, when the above-described fixed potential is a GND potential, a decreased power consumption in the semiconductor device 1 can be achieved.

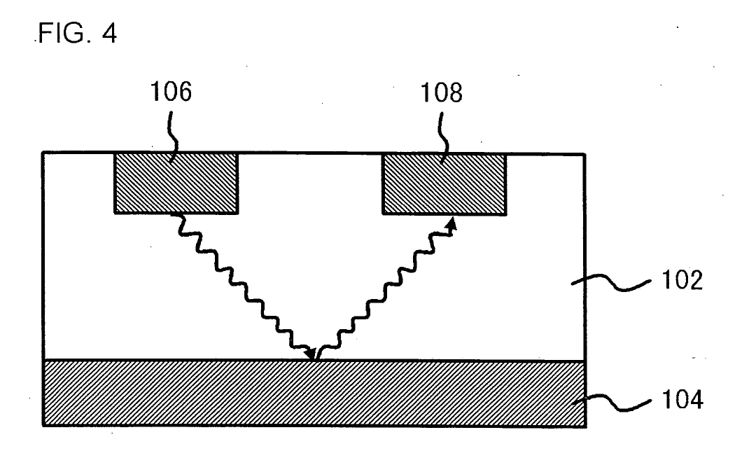

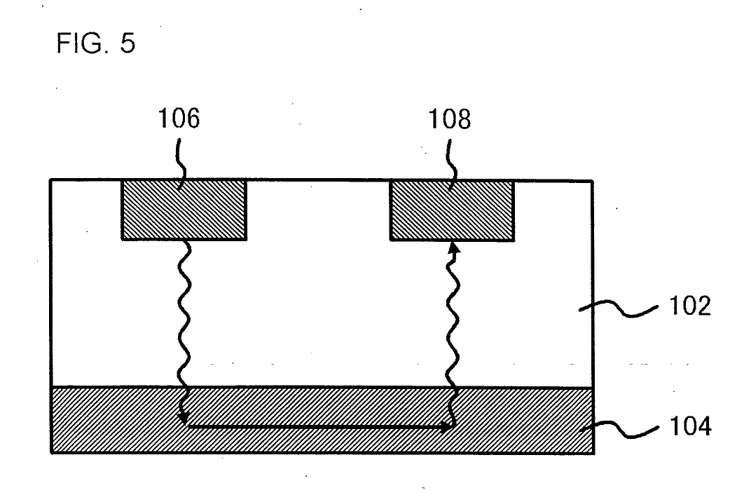

If the thickness of the semiconductor chip 20 is equal to or less than 300 μm, sufficiently thinner semiconductor device 1 can be obtained. However, in such case, the issue described in reference to FIG. 4 (issue of reflection) and the issue described in reference to FIG. 5 (issue of short-circuit) are considerable. This will be further described in reference to FIGS. 4 and 5 that thinner semiconductor substrate 102 promotes more easy attainment of noise generated in the impurity diffusion layer 106 to the heat sink 104. Therefore, in such case, the semiconductor device 1, which is capable of absorbing noise at the back surface S1 of the semiconductor chip 20, is particularly useful.

The whole back surface S1 of the semiconductor chip 20 is covered with the heat sink 30. When the whole back surface of the semiconductor chip is covered with an electroconductive member in this way, the issue of reflection and the issue of short-circuit are more considerable, as compared with a case that only a portion thereof is covered. Therefore, also in this case, the semiconductor device 1, which is capable of absorbing noise at the back surface S1 of the semiconductor chip 20, is particularly useful.

The heat sink 30 is employed as the electroconductive member. This provides the semiconductor device 1 that exhibits an improved heat release-ability.

The support frame 40 for supporting the heat sink 30 is provided on the substrate 10. This provides the semiconductor device 1 that exhibits sufficient mechanical strength. Since larger area of the heat sink 30 can be presented while assuring sufficient mechanical strength, further improved heat release-ability of the semiconductor device 1 can be achieved. Further, since the sidefill resin 54 is provided between the semiconductor chip 20 and the support frame 40, still further improvement in the mechanical strength of the semiconductor device 1 can be achieved.

A fixed potential is applied to the back surface S1 of the semiconductor chip 20 via the support frame 40. More specifically, the support frame 40 functions as a path for applying a fixed potential to the back surface S1. In this configuration, a fixed potential can be applied to the back surface S1 by a simple structure.

Meanwhile, the following issue may also be caused in the conventional semiconductor devices, in addition to the issue of reflection and the issue of short-circuit. More specifically, an issue is caused that the heat sink incidentally functions as an antenna, and noise picked up by the heat sink propagates to the semiconductor chip (issue of antenna). On the other hand, in semiconductor device 1 according to the present invention, since a fixed potential is applied to the back surface S1 of the semiconductor chip 20 via the interconnect 14 according to the semiconductor device 1, such issue can also be solved.

Further, in recent years, in order to improve thermal conductivity of a thermal path extending from the semiconductor chip to the heat sink to improve heat release-ability, a member having low electric resistance (for example, member composed of gold (Au)) is tended to be employed as a member interposing therebetween. Actually in the semiconductor device 1, the electroconductive adhesive agent 32 is provided between the semiconductor chip 20 and the heat sink 30. However, such member is also capable of promoting a propagation of noise through the semiconductor chip, similarly to the heat sink. Therefore, lower resistivity thereof causes more considerable problems of various issues as described above (issues of reflection, short-circuit and antenna). Therefore, also in such case, the semiconductor device 1, which is capable of absorbing noise at the back surface S1 of the semiconductor chip 20, is particularly useful.

The semiconductor chip 20 is flip-chip mounted on the substrate 10. In the case of the flip-chip mounting, in order to promote an emission of heat generated in semiconductor chip, a heat sink may be often provided on the back surface thereof. Therefore, the semiconductor device 1, which is capable of preventing a propagation of noise through the heat sink, is particularly useful.

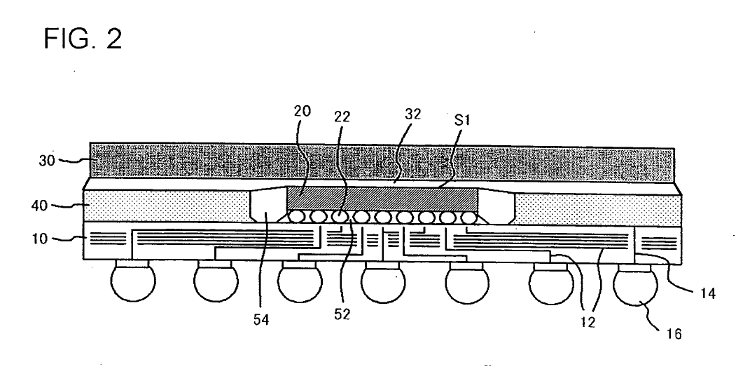

It is not intended that the semiconductor device according to the present invention is limited to the configurations illustrated in the above-described embodiment, and various modifications thereof are available. While the configuration of applying a fixed potential to the back surface S1 of the semiconductor chip 20 via the heat sink 30 has been, for example, illustrated in the above-described embodiment, a configuration of applying a fixed potential without utilizing the heat sink 30 may alternatively be employed, as shown in FIG. 2. Since the electroconductive adhesive agent 32 is provided to continuously extend from semiconductor chip 20 to support frame 40 in FIG. 2, the semiconductor chip 20 is electrically coupled directly to the support frame 40 via the electroconductive adhesive agent 32.

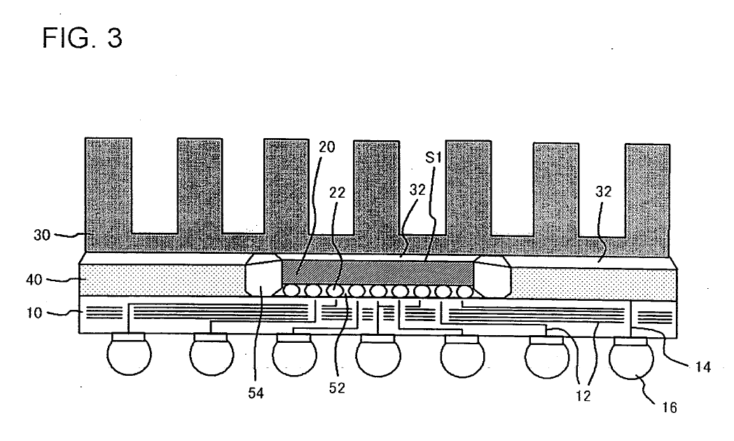

In addition, while the flat electroconductive member is illustrated in the above-described embodiment, an electroconductive member having concavity and convexity provided on the surface thereof may alternatively be employed, as shown in FIG. 3. In FIG. 3, fins are formed in one side of the heat sink 30 (side opposite to the side facing semiconductor chip 20), and the fins composes the above-described concavity and convexity.

It is apparent that the present invention is not limited to the above embodiment, and may be modified and changed without departing from the scope and spirit of the invention.

What is claimed is:

1. A semiconductor device, comprising:
a substrate;
a semiconductor chip provided on said substrate;
an electroconductive member provided on a first surface of said semiconductor chip, said first surface being a surface that is an opposite side of a surface thereof facing said substrate;
a first interconnect, provided in said substrate and electrically coupled to an internal interconnect of said semiconductor chip; and
a second interconnect, provided in said substrate and electrically coupled to said first surface of said semiconductor chip,
wherein a predetermined fixed potential is applied to said first surface of said semiconductor chip through said second interconnect, and said first interconnect is electrically insulated from said second interconnect in said substrate.

2. The semiconductor device according to claim 1, wherein said fixed potential is ground potential.

3. The semiconductor device according to claim 1, wherein a thickness of said semiconductor chip is equal to or less than 300 fÊm.

4. The semiconductor device according to claim 1, wherein said electroconductive member covers the entire of said first surface of said semiconductor chip.

5. The semiconductor device according to claim 1, wherein said electroconductive member is a heat sink.

6. The semiconductor device according to claim 5, wherein
said heat sink is fixed to said first surface of said semiconductor chip via an electroconductive adhesive agent.

7. The semiconductor device according to claim 1, further comprising an electroconductive support member, said electroconductive support member being provided on said substrate and being capable of supporting said electroconductive member, wherein said fixed potential is applied to said first surface of said semiconductor chip through said second interconnect and said support member.

8. The semiconductor device according to claim 1, wherein said semiconductor chip is flip-chip mounted on said substrate.
